(19) United States
(12) Patent Application Publication
(10) Pub. No.: US 2014/0165382 A1
(43) Pub. Date: Jun. 19, 2014

(54) METHOD FOR DETECTING REGION OF CRYSTAL ELEMENT, METHOD FOR FABRICATING CRYSTAL RESONATOR, AND METHOD FOR FABRICATING OSCILLATOR

(71) Applicant: NIHON DEMPA KOGYO CO., LTD., TOKYO (JP)

(72) Inventor: MITSUAKI KOYAMA, SAITAMA (JP)

(73) Assignee: NIHON DEMPA KOGYO CO., LTD., TOKYO (JP)

(21) Appl. No.: 14/102,456

(22) Filed: Dec. 10, 2013

(30) Foreign Application Priority Data
Dec. 13, 2012 (JP) 2012-272522

(51) Int. Cl. G01N 27/02; H03H 3/00; G01N 25/00

(52) U.S. Cl. CPC G01N 27/02; G01N 25/00; H03H 3/00
USPC 29/593; 324/693

(57) ABSTRACT

A method for detecting a boundary region between a first region and a second region, which have mutually different positive/negative X-axis direction, formed on a common crystal element includes: supporting the crystal element to a supporting portion; subsequently, obtaining an electrical characteristic value of each divided region by applying an electric signal to each of a plurality of divided regions using a pair of electrodes connected to an oscillator circuit, the plurality of divided regions being formed by dividing the crystal element into a plurality of regions in a surface direction, the pair of electrodes being arranged so as to mutually face via the crystal element in a thickness direction; and outputting information to recognize the boundary between the first region and the second region based on information where location information and the electrical characteristic values of each of the divided regions are linked.

### CROSS REFERENCE TO RELATED APPLICATIONS

This application claims the priority benefit of Japan application serial no. 2012-272522, filed on Dec. 13, 2012. The entirety of the above-mentioned patent application is hereby incorporated by reference herein and made a part of this specification.

### FIELD

This disclosure relates to a method for detecting a boundary region between a first region and a second region in a crystal element with the first region and the second region whose positive/negative directions of an X-axis differ from one another in the surface. The disclosure relates to a method for fabricating a crystal resonator and an oscillator using the method.

### DESCRIPTION OF THE RELATED ART

A crystal resonator is widely used in an industrial field such as information, communications, and sensor. In particular, in a communications field, stability of frequency is often requested to be equal to or less than ±1 ppm. To achieve such request, a Temperature Compensated Crystal Oscillator (TCXO) and an Oven Controlled Crystal Oscillator (OCXO), for example, are widely used.

As a temperature sensor, for example, a thermistor has been used in TCXO. Temperature information detected by the thermistor is converted into an electric signal, this electric signal goes through a temperature control circuit and controls a temperature characteristic of a crystal controlled oscillator. Thus, a predetermined frequency stability is ensured. However, there is time difference in temperature reaction between the crystal resonator and the thermistor. This gives rise to a problem of the thermistor being difficult to apply to products on which severe demands regarding frequency stability are made.

The inventor has examined the following crystal controlled oscillator. An AT-cut crystal element is partially heated, for example, and a DT cut region where positive and negative are inverted with respect to the X-axis of the original crystal element is formed. The region of the unheated original crystal element is referred to as a quartz crystal portion while the DT cut region is referred to as β quartz crystal portion. Frequency-temperature characteristic at the α quartz crystal portion is expressed by cubic curve while frequency-temperature characteristic at the β quartz crystal portion is expressed by first order curve. Using the oscillation frequency of the β quartz crystal portion (fundamental wave) as a temperature detection signal, a signal corresponding to the frequency setting value of the a quartz crystal portion is corrected based on the signal, thus high-accurate temperature compensation can be expected. However, a boundary between the α quartz crystal portion and the β quartz crystal portion is not optically seen including visual check. The boundary can be determined by measuring the permittivity and by X-rays; however, this has a drawback of requiring long time. The recent crystal element has an area of approximately equal to or less than 1 mm², hence an X-ray apparatus tends to be expensive.

Japanese Patent Publication No. 2003-69374 (paragraph 0008) discloses a method where a crystal element is immersed into HF (hydrogen fluoride) for etching, and the boundary is determined by the difference in etching rate between the α quartz crystal portion and the β quartz crystal portion. However, since this method is often employed as a fracture test, introducing the method into a production process causes a drawback of long time and expensive cost including processes before and after the etching.

A need thus exists for a method for detecting region of crystal element, a method for fabricating crystal resonator, and a method for fabricating oscillator which are not susceptible to the drawbacks mentioned above.

### SUMMARY

A method for detecting a region of a crystal element according to this disclosure is a detection method that detects a boundary region between a first region and a second region formed on a common crystal element. The first region and the second region have mutually different positive/negative X-axis direction. The method for detecting a region of a crystal element includes: supporting the crystal element onto a supporting portion; subsequently, an electrical characteristic value obtaining step, applying an electric signal to each of a plurality of divided regions using a pair of electrodes connected to an oscillator circuit to obtain an electrical characteristic value of each the plurality of divided regions, the plurality of divided regions being formed by dividing the crystal element into a plurality of regions in a surface direction, the pair of electrodes being arranged so as to mutually face via the crystal element in a thickness direction of the crystal element; and outputting information for recognizing a boundary between the first region and the second region based on information where location information and the electrical characteristic values of each of the divided regions are linked.

### BRIEF DESCRIPTION OF THE DRAWINGS

The foregoing and additional features and characteristics of this disclosure will become more apparent from the following detailed description considered with reference to the accompanying drawings, wherein:

FIG. 1A is a plan view of a crystal element with twins, FIG. 1B is a side view of the crystal element with twins;

FIG. 2 is a side view illustrating an inspection apparatus for the crystal element according to a first embodiment;

FIG. 3 is a block diagram illustrating an overall configuration of the inspection apparatus for the crystal element according to the first embodiment;

FIG. 4 is a side view illustrating a configuration of a second embodiment;

FIG. 5 is a plan view illustrating the configuration of the second embodiment;

FIG. 6A to FIG. 6C are explanatory drawings illustrating a fabrication process of a crystal resonator according to the embodiment of this disclosure;

FIG. 7 is a circuit diagram of a temperature compensation oscillator including the crystal unit; and

FIG. 8 is a characteristic diagram illustrating a determination result of the crystal element according to the embodiment.

### DETAILED DESCRIPTION

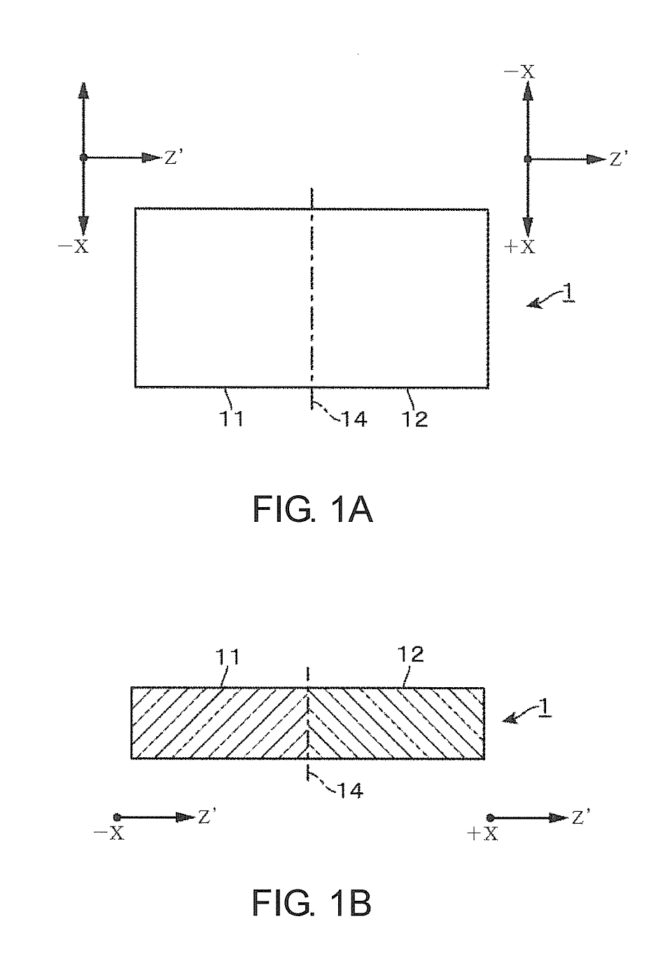

Before describing embodiments of this disclosure, a crystal element subject to an inspection will be described. A crystal element 1 illustrated in FIG. 1A and FIG. 1B has a rectangular shape. The crystal element 1 is, for example, formed with a short side of 2.5 mm and a long side of 5.0 mm. The crystal element 1 is, for example, divided in two left-to-right by a center line 14 passing through the centers of the mutually opposing longer sides. For convenience of explanation, the crystal element 1 divided into two regions at the center line 14 of the crystal element 1 is illustrated. In the crystal element 1 where twins are formed, each of the first crystal region (hereinafter referred to as “α quartz crystal portion”) 11 and the second crystal region (hereinafter referred to as “β quartz crystal portion”) 12 is formed along the longitudinal direction of the crystal element 1, for example. The α quartz crystal portion 11 is formed parallel to a surface formed with Z′-axis, which is inclined approximately 35° counterclockwise with respect to a Z-axis viewed from the + direction of the X-axis, and the X-axis. The Z-axis is a crystallographic axis with the front surface and the rear surface formed of a crystal. That is, the α quartz crystal portion 11 is AT-cut region. The β quartz crystal portion 12 is formed such that the front surface and the rear surface are parallel to a surface formed with the Z′-axis and the X-axis. The positive/negative direction of the X-axis is configured to be inverse to the positive/negative direction of the X-axis of the α quartz crystal portion 11. That is, this crystal element 1 is configured as electrical twins. The βquartz crystal portion 12 is configured as about DT-cut region.

### First Embodiment

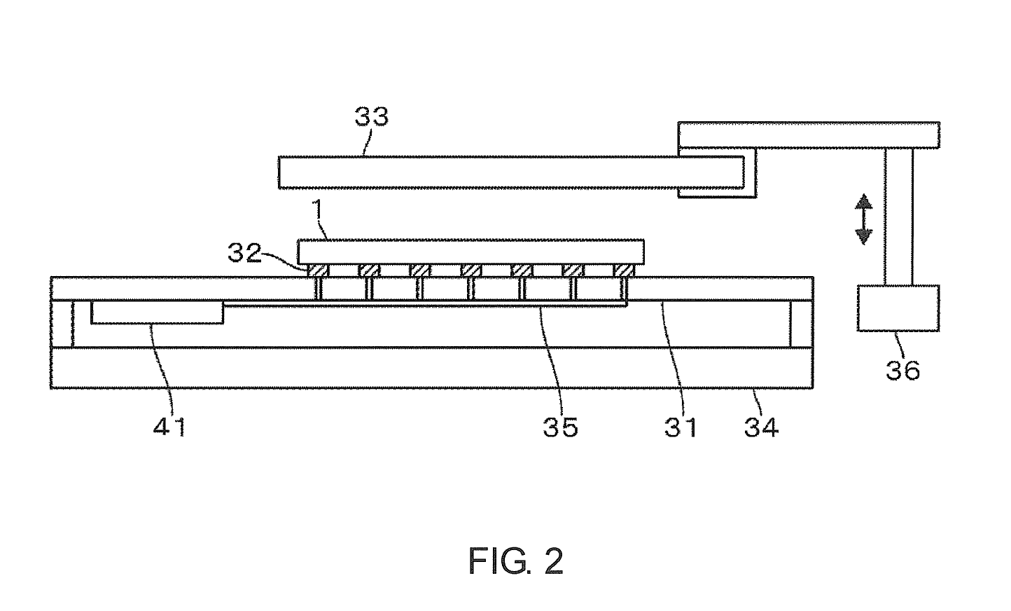

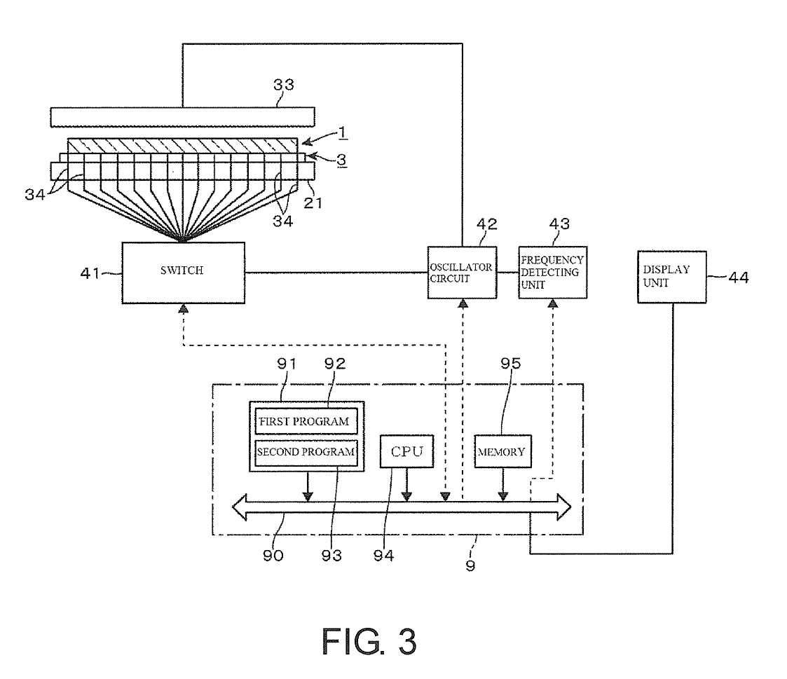

An exemplary inspection apparatus for the crystal element used for the embodiments of this disclosure will be described. FIG. 2 is a block diagram illustrating the whole inspection apparatus for the crystal element 1. FIG. 3 is a block diagram illustrating an overall configuration of the inspection apparatus for the crystal element according to the first embodiment. Reference numeral 21 in the drawing is a mounting table, which is a supporting portion. To the mounting table 21, for example, the plate-shaped crystal element 1 is placed in a horizontal posture. The mounting table 21 includes a square-shaped substrate body 34 with an open top surface. The mounting table 21 includes a rectangular detection electrode plate 3 at a portion where the crystal element 1 is placed. The detection electrode plate 3 includes a detection electrode 32 on the top surface of an insulating substrate 31 made of, for example, resin. The detection electrode 32 is, for example, a circular plate-shaped electrode with a diameter of 2.5 μm. The detection electrodes 32 are arranged in a matrix on a top surface of the insulating substrate 31 with a distance of 2.5 μm between them and are formed by, for example, sputtering Au. An address (two-dimensional coordinate position) corresponding to “row” and “column” of an arrangement pattern of the detection electrode 32 group is assigned for each detection electrode 32. The insulating substrate 31 includes a group of bumps (not shown) arranged corresponding to the detection electrodes 32 on the other surface. Each detection electrode 32 is connected to the corresponding bump via a through-hole of the insulating substrate 31. Each bump is connected to a switch 41 via a conductive path 35 on the other surface side of the substrate 31.

An aluminum electrode 33 is disposed above the detection electrode plate 3 via the arrangement space of the crystal element 1. The aluminum electrode 33 has a larger area than the arrangement region of the detection electrode 32. The aluminum electrode 33 is free to travel up and down with an elevation mechanism 36. The height position of the aluminum electrode 33 is adjustable according to the thickness of the crystal element 1. As shown in FIG. 3, the switch 41 connects to one end side of an oscillator circuit 42 constituted of, for example, a Colpitts circuit. Switching the switch 41 switches the detection electrode 32 connected to the oscillator circuit 42. The other end side of the oscillator circuit 42 is connected to the aluminum electrode 33. Applying a DC current to the oscillator circuit 42 oscillates the region sandwiched between the aluminum electrode 33 and the detection electrode 32 selected by the switch 41. In this example, the detection electrode 32 and the aluminum electrode 33 form a pair of electrodes. To the latter part of the oscillator circuit 42, a frequency detecting unit 43 is connected. The frequency detecting unit 43 detects a frequency of high frequency output from the oscillator circuit 42. A frequency counter, for example, is used for the frequency detecting unit 43. In the first embodiment, the oscillator circuit 42 and the frequency detecting unit 43 are detecting units for electrical characteristic value and the detected frequency corresponds to the electrical characteristic value.

The inspection apparatus for the crystal element includes a controller 9 constituted of a computer. Reference numeral 90 in the drawing denotes a bus. The bus 90 connects a program storage unit 91, which stores a first program 92 and a second program 93, a CPU 94, which performs an arithmetic operation, and a memory 95, which is a storage unit. The bus 90 connects, for example, a display unit 44, which is a liquid crystal display. The display unit 44 displays an output from the controller 9. The first program 92 incorporates the following steps. The switch 41 is switched in the predetermined order to change the detection electrode 32 connected to the oscillator circuit 42 while the oscillator circuit 42 is oscillated to obtain oscillation frequencies at each region by the frequency detecting unit 43. When the address of the detection electrode 32 corresponding to the channel selected by the switch 41 and the frequency information detected by the frequency detecting unit 43 are input to the memory 95, for example, the memory 95 stores a data table, for example, that links the coordinate number of the detection electrode 32 to another region of the memory 95.

The second program 93 includes the following steps. The frequency of the divided region of the crystal element 1 corresponding to each detection electrode 32 is converted into gray scale density. Then, a table that links the address of each divided region (address corresponding to the address of each detection electrode) with the density is created. The gray scale density is, for example, indicated by a value divided into 256 gradations. The gray scale densities are set according to the regions of the assumed oscillation frequency of the crystal element 1 subject to the determination. According to the gradation range of the gray scale, the α quartz crystal portion 11 and the β quartz crystal portion 12 are determined. That is, different from the oscillation frequency of the α quartz crystal portion 11 and the frequency of the β quartz crystal portion 12, in the case where, for example, the AT-cut crystal element 1 is used and the resonance frequency is approximately 28 MHz, the β quartz crystal portion 12 has an approximately frequency of 55 MHz.

Accordingly, a method that sets, for example, less than 28 MHz as a first gradation, a frequency exceeding 55 MHz as a 256th gradation (density) and equally divides 28 MHz to 55 MHz into, for example, 254 levels to set 2th to 255th gradations (densities) is available. The second program 93 further includes a step that links each divided region of the crystal element 1 with the density corresponding to the gradation based on the gradation table thus obtained and displays them on the display unit 44. The display unit 44 displays an arithmetic operation result by the second program 93. The display unit 44 displays grids divided into N×M regions created by the second program 93, for example. Each grid is output in a color gradation of the density corresponding to the frequency and displayed as a two-dimensional map. The first program 92 and the second program 93 are stored in the program storage unit 91 constituted of a storage medium, for example, a flexible disk, a compact disk, a hard disk, a magnet-optical disk (MO), and a memory card and installed to the controller 9.

An operation of the above-described inspection apparatus for the crystal element 1 will be described. When the crystal element 1 subject to detection is placed on the mounting table 21, first, the height position of the aluminum electrode 33 is adjusted to the height position opposed to the crystal element 1 placed on the detection electrode plate 3 via a gap of approximately 1 to 5 μm. Then, using the switch 41, the oscillator circuit is sequentially connected to the matrix-arranged detection electrodes 32 to obtain the oscillation frequencies of the divided regions (vibration regions) of the crystal element 1, which is sandwiched between each detection electrode 32 and the aluminum electrode 33. The frequency liked to the address of the divided region (address of the detection electrode) is written to the table in the memory. Further, each frequency value is converted into a density value corresponding to the gray scale of 256 gradations as described above. The density value is written in the table being linked to the address of the divided region. Based on the data in the table, the display unit 44 displays an image linking the divided regions and the gray scales.

The following describes a case where, for example, the crystal element 1 of 5.0 mm×2.5 mm with twins formed by the above-described method is subject to detection. An AT-cut crystal element 1 is used for the crystal element 1. Phase transition is assumed to be attempted on the crystal element 1 by heating the region of 2.5 mm of the crystal element 1 in the longitudinal direction at 600° C. In the crystal element 1, the following describes the AT-cut region as the α quartz crystal portion while the DT cut region with a phase-transition is assumed to be the β quartz crystal portion.

The oscillation frequency at the region of the α quartz crystal portion 11 of the crystal element 1 is approximately 26 MHz in the fundamental wave oscillation. In contrast to this, since the region of the β quartz crystal portion 12 is DT-cut by phase transition, the frequency becomes approximately 55 MHz. The region of the α quartz crystal portion 11 and the region of the β quartz crystal portion differ approximately 29 MHz from one another and therefore the oscillation frequencies at the respective regions greatly differ. Since oscillation does not occur in the detection electrode 32 where the crystal element 1 is not placed above, the output frequency becomes almost 0.

In the regions of each of the α quartz crystal portion 11 and the β quartz crystal portion 12, the frequencies are hardly changed. Accordingly, in a two-dimensional map output to the display unit 44, the region where the crystal element 1 is placed is divided by coloring into zones displayed in the gradation density corresponding to the frequency of 55 MHz and a zone displayed in the gradation density corresponding to the frequency of 26 MHz. The region where the crystal element 1 is not placed is displayed by the gradation density corresponding to the frequency of almost 0. In the case where a boundary layer between the α quartz crystal portion 11 and the β quartz crystal portion 12 is placed across at the top portion of the detection electrode 32 or in the case where the interfacial boundary between the α quartz crystal portion 11 and the β quartz crystal portion 12 is obliquely inclined with respect to the perpendicularly upward direction and a specific region of the crystal placed on the detection electrode 32 includes the α quartz crystal portion 11 and the β quartz crystal portion 12, the frequencies oscillated at the respective regions are mixed and then output. Accordingly, the frequencies are output in different gradation densities. However, this region is just a slight region near the interfacial boundary between the α quartz crystal portion 11 and the β quartz crystal portion 12. In the above-described inspection apparatus for the crystal element, the distance of arrangement of the detection electrodes is set a narrow of 5.0 μm. With this accuracy, the α quartz crystal portion and the β quartz crystal portion of the crystal element can be displayed by being colored differently.

According to the above-described embodiment, an electrical characteristic value such as an oscillation frequency of each divided region, which is the first region 11 and the second region 12, whose positive/negative directions of the X-axis differ from one another, of the crystal element 1 is obtained with the pair of electrodes 32 and 33. The pair of electrodes 32 and 33 are connected to the oscillator circuit 42 and disposed on both surfaces sides of the crystal element 1. Based on the obtained electrical characteristic value and the location information of the divided regions, information to recognize the boundary between both regions is output. Accordingly, the first region 11 and the second region 12 can be easily detected.

Alternatively, the detected frequency information may be distinguished by threshold, the crystal element 1 may be determined whether the region is the α quartz crystal portion 11 or the β quartz crystal portion 12, and the α quartz crystal portion 11 may be displayed in bright luminance while the β quartz crystal portion 12 may be displayed in dark luminance. The case where the frequency is attempted to be detected without through the crystal element 1 is displayed as a blank. In the case where the crystal element 1, for example, has a thickness of 44 μm with an AT-cut α crystal region and a β crystal region for which phase transition has been performed, the oscillation frequency of the α quartz crystal portion 11 is approximately 28 MHz while the oscillation frequency of the β quartz crystal portion 12 is approximately 55 MHz. The threshold may be set to, for example, 40 MHz, less than 40 MHz may be determined as the α quartz crystal portion 11, and equal to or more than 40 MHz may be determined as the β quartz crystal portion 12.

### Modification of First Embodiment

In a configuration of the inspection apparatus for the crystal element, as a detecting unit for electrical characteristic value, a network analyzer may be used instead of using the oscillator circuit 42 and the frequency detecting unit 43. The network analyzer applies an alternating current with a predetermined frequency to a measuring object and receives reflected wave reflected from the measuring object and transmitted wave that has passed through the measuring object at the receiving unit. Mutually comparing the applied input wave, the received reflected wave, and the transmitted wave allows calculating, for example, the attenuation characteristic, a gain characteristic, and a motional resistance of the measuring object. These values may be employed as electrical characteristic values. When the specific region of the crystal element 1 placed on the selected detection electrode 32 is the α quartz crystal portion 11, the resonance frequency of the region is approximately 26 MHz. When the region of the crystal element 1 placed on the selected detection electrode 32 is the β quartz crystal portion 12, the resonance frequency of the region is approximately 56 MHz. In the case where an alternating current of 26 MHz is applied to the crystal element 1 with twins of the α quartz crystal portion 11 and the β quartz crystal portion 12, since, for example, the attenuation characteristic detected from each region differ, the attenuation characteristics can be binarized. Additionally, in the case where the two-dimensional map is created using the measured attenuation characteristic value as the electrical characteristic value, the α quartz crystal portion 11 and the β quartz crystal portion 12 can be colored differently. Accordingly, each region can be determined. As the electrical characteristic value, it is only necessary that the value can distinguish the α quartz crystal portion 11 and the β quartz crystal portion 12, and the gain characteristic and the motional resistance may be used. Depending on the characteristic of the crystal constituting the α quartz crystal portion 11 and the β quartz crystal portion 12, the electrical characteristic value is preferred to be changed.

### Second Embodiment

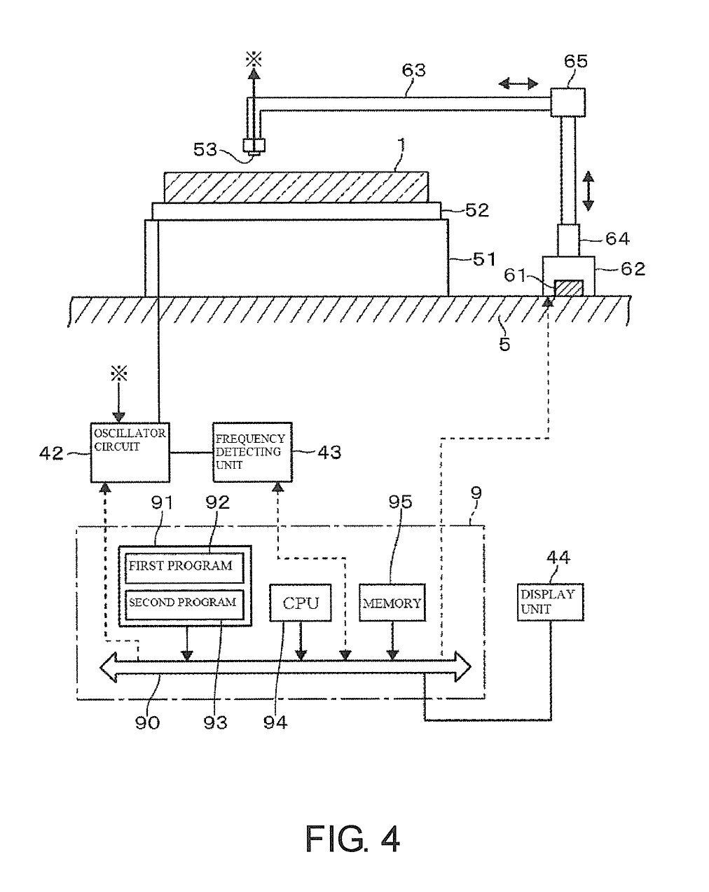

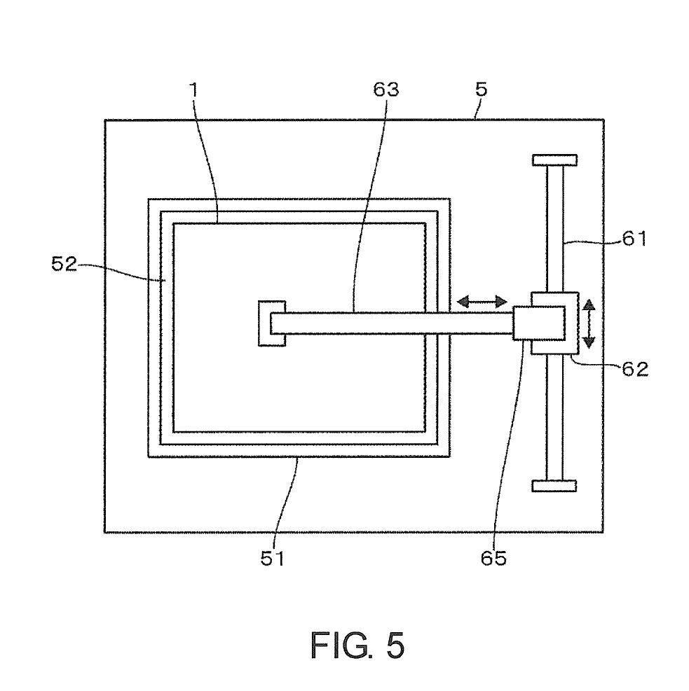

An inspection apparatus for the crystal element according to the second embodiment will be described. As shown in FIG. 4 and FIG. 5, a mounting table 51 where the crystal element 1 is placed is disposed on a base 5. A rectangular aluminum electrode 52, for example, is installed on the top surface of the mounting table 51. A guide rail 61, which extends in the width direction of the base 5, is disposed on the top surface of the base 5. A moving body 62 is installed at the guide rail 61. The moving body 62 is configured movable in the width direction of the base 5 along the guide rail 61 in accordance with, for example, driving of a ball screw. The moving body 62 is provided with a supporting arm 63. The moving body 62 slides vertically upward and beyond that slides in the longitudinal direction of the base 5 in the drawing. The supporting arm 63 includes an elevation mechanism 64 and an expansion mechanism 65. The elevation mechanism 64 is constituted free to travel up and down along an upright direction. The expansion mechanism 65 is freely expanded in the longitudinal direction of the base 5. The supporting arm 63 includes a circular plate-shaped detection electrode 53 with diameter of, for example, 2.5 μm at the distal end. The aluminum electrode 52 and the detection electrode 53 form a pair of electrodes. The moving body 62 and the expansion mechanism 65 can adjust the horizontal position of the detection electrode 53, for example, at 5-μm intervals by movement and expansion and contraction of the moving body 62 and the expansion mechanism 65, and therefore can be referred to as a detection position change unit.

The detection electrode 53 and the aluminum electrode 52 connect to the oscillator circuit 42 constituted of, for example, a Colpitts circuit. The frequency output from the oscillator circuit 42 is input to the frequency detecting unit 43. The controller 9 is also connected to the inspection apparatus for the crystal element according to the second embodiment. The first program 92, which is stored in the controller 9, includes the following step instead of the step for switching the channel of the switch. The step horizontally moves the detection electrode 53 to above the crystal element 1, which is subject to determination. The region above the aluminum electrode 52 is partitioned to the divided regions arranged in a matrix with grids of 5 μm×5 μm, for example. Then, two-dimensional coordinates indicated by A and B are given to each partition. The first program first moves the detection electrode 53 to the height position upward of 1 to 5 μm from the top surface of the crystal element 1, and then moves the detection electrode 53 to an inspection start position, for example, the center position of the grid formed of (A1, B1) coordinates. Then, the crystal element 1 is oscillated and the oscillation frequency is obtained. Then, the position of the detection electrode 53 is intermittently and sequentially moved to another grid, then the oscillator circuit 42 is oscillated. As a result, oscillation is performed on all grids, thus obtaining the frequencies. The obtained frequency information is stored in the memory 95 together with the coordinate information of the region detected by the detection electrode 53. Similarly to the first embodiment, the arithmetic operation is performed by the second program 93, and a two-dimensional map, for example, is created and is output to the display unit 44. This configuration also allows obtaining the similar result.

### Working Example

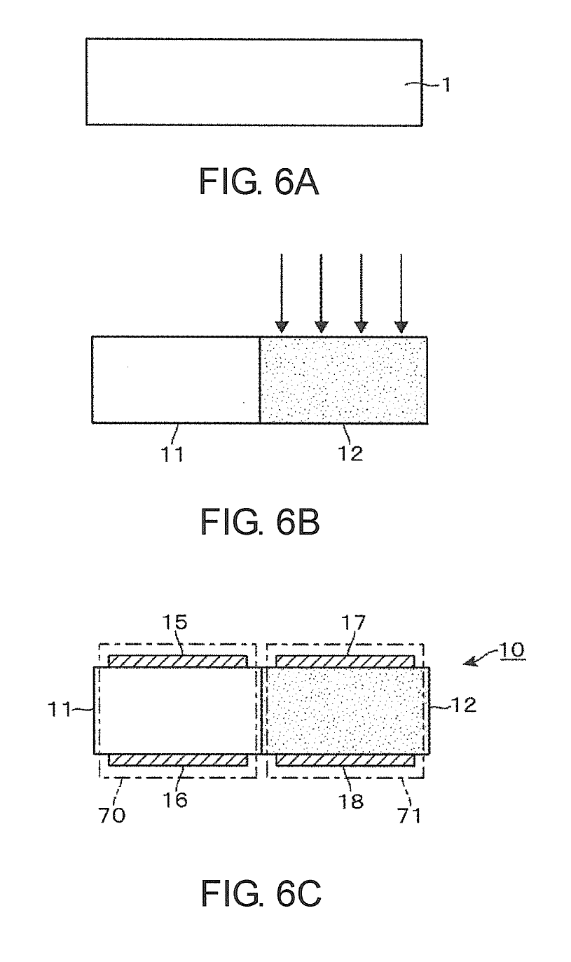

An working example using the detection method according to this disclosure includes the method for fabricating an oscillation device. First, twins are formed at the AT-cut rectangular crystal element 1 as shown in FIG. 6A. As shown in FIG. 6B, for example, the crystal element 1 is divided into two regions in the longitudinal direction. One region is masked and laser-irradiated. The one region where laser is not irradiated becomes the AT-cut α quartz crystal portion 11. In the other region, the X-axis is inverted, and the other region becomes the β quartz crystal portion 12, which is a DT cut region. The boundary line between each of the regions is detected by the above-described method for detecting the regions of the crystal element. Then, as shown in FIG. 6C, excitation electrodes 15, 16, 17, and 18 are formed with, for example, Au, on both surfaces of each of the α quartz crystal portion 11 and the β quartz crystal portion 12, thus obtaining a crystal resonator 10.

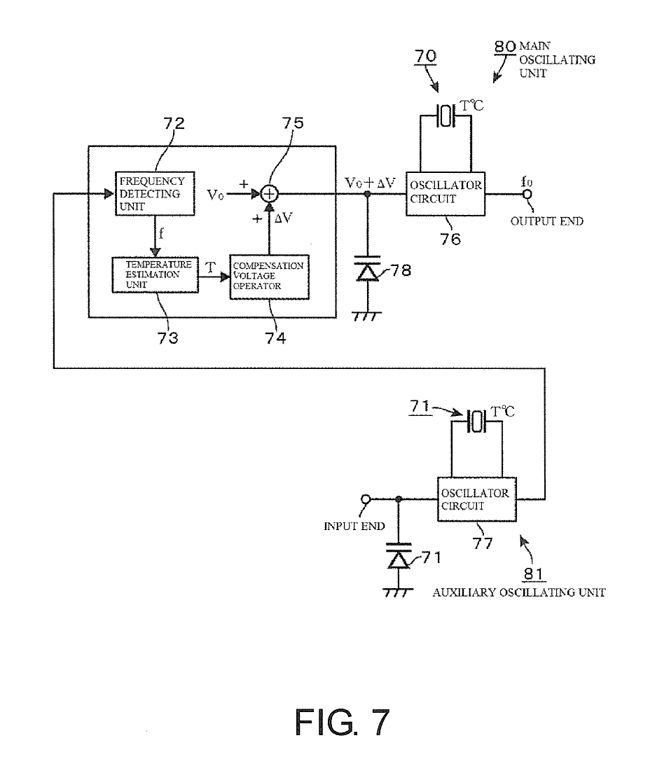

Thereafter, the crystal resonator 10 is housed in a package. This package is mounted on a printed circuit board together with the oscillator circuit and the peripheral element, thus obtaining the oscillation device. FIG. 7 is an exemplary oscillation device and a temperature compensated crystal oscillator constituted using the above-described crystal resonator. Since the above-described crystal resonator includes two vibration regions that vibrate independently, this description indicates the crystal resonator as two crystal resonators for convenience. Reference numeral 70 denotes a first crystal resonator formed at the α quartz crystal portion while reference numeral 71 denotes a second crystal resonator formed at the β quartz crystal portion.

In this TCXO, an auxiliary oscillating unit 81 constituted of an oscillator circuit 77 connected to the second crystal resonator 71 is first oscillated and a high frequency is output. The high frequency, a frequency f, is detected by a frequency detecting unit 72 and the frequency f is input to a temperature estimation unit 73. The temperature estimation unit 73 calculates an ambient temperature T of the crystal resonator 10 from the frequency information. A compensation voltage operator 74 calculates a compensation voltage ΔV from the calculated temperature T. The compensation voltage ΔV compensates for a frequency error of the oscillation frequency of the first crystal resonator 70 caused by a temperature difference. The compensation voltage ΔV is added to a voltage V₀, which is input to an oscillator circuit 76, by a voltage compensation unit 75. This compensates the error of the oscillation frequency of the first crystal resonator 70 caused by temperature, allowing stabilization of an oscillation frequency f₀ of a main oscillating unit 80. Reference numerals 78 and 79 in the drawing denote varicap diodes.

Since the temperature and the rate of change of frequency of the DT cut crystal have an almost proportional relationship in a temperature zone of, for example, a room temperature of 0° C. to 30° C., a clear frequency change can be taken out. Accordingly, by using the second crystal resonator 71 as a crystal resonator for temperature compensation, an oscillator that can oscillate a stable frequency with simple configuration. The frequency detecting unit 72, the temperature estimation unit 73, the compensation voltage operator 74, and the addition unit 75 (voltage compensation unit) are disposed inside of an integrated circuit chip.

### Measurement Example

Using the above-described inspection apparatus according to the first embodiment, the crystal element 1 where the α quartz crystal portion 11 and the β quartz crystal portion 12 are formed was measured. The crystal element 1 was fabricated as follows. Almost the half region of a crystal element of 5 min (A-axis direction) and 2.5 mm (B-axis direction) in the B-axis direction with the fundamental wave vibration mode of 26 MHz was heated at 600° C. to form the β quartz crystal portion 12 with a frequency constant of 56 MHz. The detection electrodes 32 of the inspection apparatus for the crystal element were formed in a circular shape with a diameter of 2.5 μm, respectively. The detection electrodes 32 were each arranged with a distance of 2.5 μm between the detection electrodes 32.

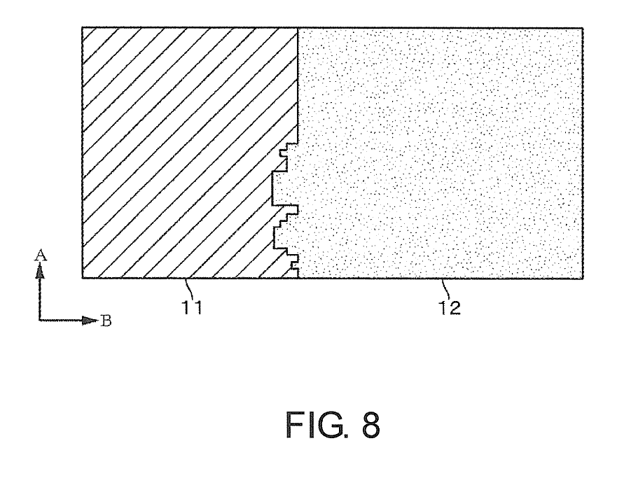

FIG. 8 illustrates the result. The horizontal axis indicates the B-axis position of the crystal element 1 while the vertical axis indicates the A-axis position of the crystal element. The frequencies at the respective positions are indicated as the two-dimensional map. The hatched regions in FIG. 6C indicates a region vibrating at 27.093 MHz while the regions vibrating at 55.749 MHz are dotted in FIG. 6B and FIG. 6C. The region where oscillation did not occur was eliminated.

According to FIG. 6C, the two regions are clearly distinguished. Since the assumed frequency at the α quartz crystal portion 11 is approximately 26 MHz, the frequency region at 27.093 MHz indicates the α quartz crystal portion 11 region. Since the assumed frequency at the β quartz crystal portion 12 is approximately 56 MHz, the frequency region at 55.749 MHz indicates the β quartz crystal portion 12 region. Near the interfacial boundary between the α quartz crystal portion 11 and the β quartz crystal portion 12 is formed with many peaks. However, the regions of the α quartz crystal portion 11 and the region of the β quartz crystal portion 12 can be clearly distinguished from respective regions. When determination is made using the above-described inspection apparatus for the crystal element, each region of the α quartz crystal portion 11 and the β quartz crystal portion 12 can be clearly divided.

The method for determining a crystal element according to this disclosure may be configured as follows. The obtaining electrical characteristic value may obtain an oscillation frequency by vibrating each divided region with the pair of electrodes connected to an oscillator circuit. The obtaining electrical characteristic value may obtain an electrical characteristic value of each divided region by: forming a state where a plurality of electrodes, which are electrodes of one side of the pair of electrodes and correspond to the plurality of respective divided regions, are arranged on one surface side of the crystal element; and relatively and sequentially moving an electrode of the other side of the pair of electrodes at the other side of the crystal element to a position corresponding to the plurality of respective divided regions.

A method for fabricating a crystal resonator according to this disclosure may include: a forming step, forming a region with a direction of an X-axis that is opposite of a direction of an X-axis of the crystal element at a part of the crystal element; treating a region newly formed by the forming step as the second region and treating a region other than the second region as the first region; a detecting step, detecting a boundary region between the first region and the second region by the above-described method for detecting a region of the crystal element; and disposing excitation electrodes to each of the first region and the second region based on a detection result of the detecting step.

A method for fabricating an oscillator according to this disclosure may include: connecting a first oscillator circuit to an excitation electrode disposed at the first region and also connecting a second oscillator circuit to an excitation electrode disposed at the second region after fabrication of the crystal resonator with the above-described method; disposing a correction unit that estimates a temperature of the crystal resonator based on an output frequency of the second oscillator circuit and corrects a setting signal corresponding to a setting value of an oscillation frequency of a first oscillator circuit based on this estimated temperature.

In this disclosure, an electrical characteristic value, for example, an oscillation frequency of each divided region, which is the first region and the second region whose positive/negative directions of the X-axis differ from one another, of the crystal element is obtained with the pair of electrodes connected to an oscillator circuit and disposed on both surfaces sides of the crystal element. Based on the obtained electrical characteristic value and the location information of the divided regions, information to recognize the boundary between both regions is output. Accordingly, the first region and the second region can be easily detected. This facilitates operation processes of disposing an excitation electrode for output and an excitation electrode for temperature compensation at the respective first region and second region and fabricating an oscillation device.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A method for detecting a boundary region of a crystal element, the boundary region is between a first region and a second region formed on a common crystal element, the first region and the second region having mutually different positive/negative X-axis direction, the method comprising:
supporting the crystal element onto a supporting portion;
subsequently an electrical characteristic value obtaining step, applying an electric signal to each of a plurality of divided regions using a pair of electrodes connected to an oscillator circuit to obtain an electrical characteristic value of each the plurality of divided regions, the plurality of divided regions being formed by dividing the crystal element into a plurality of regions in a surface direction, the pair of electrodes being arranged so as to mutually face via the crystal element in a thickness direction of the crystal element; and
outputting information for recognizing a boundary between the first region and the second region based on information where location information and the electrical characteristic values of each of the divided regions are linked.

2. The method for detecting a region of a crystal element according to claim 1, wherein
the electrical characteristic value obtaining step obtains an oscillation frequency by vibrating each of the plurality of divided regions with the pair of electrodes connected to the oscillator circuit.

3. The method for detecting a region of a crystal element according to claim 1, wherein
the electrical characteristic value obtaining step includes:
arranging a plurality of electrodes corresponding to the plurality of respective divided regions on one surface side of the crystal element, the plurality of electrodes being electrodes of one side of the pair of electrodes; and
obtaining the electrical characteristic value of each of the plurality of divided regions by relatively and sequentially moving the other side of the pair of electrodes at the other side of the crystal element to a position corresponding to the plurality of respective divided regions.

4. The method for detecting a region of a crystal element according to claim 2, wherein
the electrical characteristic value obtaining step includes:
arranging a plurality of electrodes corresponding to the plurality of respective divided regions on one surface side of the crystal element, the plurality of electrodes being electrodes of one side of the pair of electrodes; and
obtaining the electrical characteristic value of each of the plurality of divided regions by relatively and sequentially moving the other side of the pair of electrodes at the other side of the crystal element to a position corresponding to the plurality of respective divided regions.

5. A method for fabricating a crystal resonator, comprising:
a forming step, forming a region with a direction of an X-axis that is opposite of a direction of an X-axis of the crystal element at a part of the crystal element;
treating a newly formed region formed by the forming step as the second region and treating a region other than the second region as the first region;
a detecting step, using the method according to claim 1 to detect the boundary region between the first region and the second region; and
disposing an excitation electrode to each of the first region and the second region based on a detection result of the detecting step.

6. A method for fabricating a crystal resonator, comprising:
a forming step, forming a region with a direction of an X-axis that is opposite of a direction of an X-axis of the crystal element at a part of the crystal element;
treating a newly formed region formed by the forming step as the second region and treating a region other than the second region as the first region;
a detecting step, using the method according to claim 2 to detect the boundary region between the first region and the second region; and
disposing an excitation electrode to each of the first region and the second region based on a detection result of process detecting step.

7. A method for fabricating a crystal resonator, comprising:
a forming step, forming a region with a direction of an X-axis that is opposite of a direction of an X-axis of the crystal element at a part of the crystal element;
treating a newly formed region formed by the forming step as the second region and treating a region other than the second region as the first region;
a detecting step, using the method according to claim 3 to detect the boundary region between the first region and the second region; and
disposing an excitation electrode to each of the first region and the second region based on a detection result of the detecting step.

8. A method for fabricating a crystal resonator, comprising:
a forming step, forming a region with a direction of an X-axis that is opposite of a direction of an X-axis of the crystal element at a part of the crystal element;
treating a newly formed region formed by the forming step as the second region and treating a region other than the second region as the first region;
a detecting step, using the method according to claim 4 to detect the boundary region between the first region and the second region; and
disposing an excitation electrode to each of the first region and the second region based on a detection result of the detecting step.

9. A method for fabricating an oscillator, comprising:
after using the method according to claim 5 to fabricate the crystal resonator, connect a first oscillator circuit to the excitation electrode disposed at the first region and connecting a second oscillator circuit to the excitation electrode disposed at the second region; and
estimating a temperature of the crystal resonator based on an output frequency of the second oscillator circuit and disposing a correction unit that corrects a setting signal corresponding to a setting value of an oscillation frequency of the first oscillator circuit based on the estimated temperature.

10. A method for fabricating an oscillator, comprising:
after using the method according to claim 6 to fabricate the crystal resonator, connect a first oscillator circuit to the excitation electrode disposed at the first region and connecting a second oscillator circuit to the excitation electrode disposed at the second region; and
estimating a temperature of the crystal resonator based on an output frequency of the second oscillator circuit and disposing a correction unit that corrects a setting signal corresponding to a setting value of an oscillation frequency of the first oscillator circuit based on the estimated temperature.

11. A method for fabricating an oscillator, comprising:
after using the method according to claim 7 to fabricate the crystal resonator, connect a first oscillator circuit to the excitation electrode disposed at the first region and connecting a second oscillator circuit to the excitation electrode disposed at the second region; and
estimating a temperature of the crystal resonator based on an output frequency of the second oscillator circuit and disposing a correction unit that corrects a setting signal corresponding to a setting value of an oscillation frequency of the first oscillator circuit based on the estimated temperature.

12. A method for fabricating an oscillator, comprising:
after using the method according to claim 8 to fabricate the crystal resonator, connect a first oscillator circuit to the excitation electrode disposed at the first region and connecting a second oscillator circuit to the excitation electrode disposed at the second region; and
estimating a temperature of the crystal resonator based on an output frequency of the second oscillator circuit and disposing a correction unit that corrects a setting signal corresponding to a setting value of an oscillation frequency of the first oscillator circuit based on the estimated temperature.
